(19) United States
(12) Patent Application Publication
(10) Pub. No.: US 2026/0039093 A1
(43) Pub. Date: Feb. 5, 2026

(54) LASER MODULE AND LASER PROCESSING MACHINE

(71) Applicant: SEIKO EPSON CORPORATION, Tokyo (JP)

(72) Inventor: Eiji MORIKUNI, MATSUMOTO-SHI (JP)

(73) Assignee: SEIKO EPSON CORPORATION, Tokyo (JP)

(21) Appl. No.: 19/284,614

(22) Filed: Jul. 29, 2025

(30) Foreign Application Priority Data
Jul. 30, 2024 (JP) 2024-123385

(51) Int. Cl. H01S 5/40; H01S 5/02253; H01S 5/02255; H01S 5/11; H01S 5/42

(52) U.S. Cl. CPC H01S 5/4012; H01S 5/02253; H01S 5/02255; H01S 5/42; H01S 5/11

(57) ABSTRACT

A laser module includes first and second laser light sources provided on a plane and emit first light and second light, a first mirror reflecting the first light, a second mirror transmitting the first light reflected by the first mirror and reflects the second light, and first and second condensing optical systems provided between the first and second laser light sources and the first and second mirrors, in which a radiation angle of the first light is smaller than a radiation angle of the second light, a distance between the first laser light source and a principal point of the first condensing optical system is greater than a distance between the second laser light source and a principal point of the second condensing optical system, and an optical path length from the first laser light source to the second mirror is greater than an optical path length from the second laser light source to the second mirror.

The present application is based on, and claims priority from JP Application Serial Number 2024-123385, filed Jul. 30, 2024, the disclosure of which is hereby incorporated by reference herein in its entirety.

### BACKGROUND

### 1. Technical Field

The present disclosure relates to a laser module and a laser processing machine.

### 2. Related Art

In order to achieve a high output, a laser module that multiplexes and emits light from a plurality of semiconductor laser light sources is known.

For example, JP-A-2000-141757 discloses a light beam exposure device including a plurality of light source units that have different wavelength characteristics, a dichroic mirror that multiplexes light beams having different wavelength characteristics and emitted from the plurality of light source units, and an imaging optical system that irradiates an exposure surface with the light beams from the dichroic mirror.

However, in the light beam exposure device disclosed in JP-A-2000-141757, since the plurality of light source units are provided in a stepped manner, it is difficult to adjust the positions of the plurality of light source units.

### SUMMARY

According to an aspect of the present disclosure, a laser module includes
a first substrate,
a first semiconductor laser light source that is provided on a first plane of the first substrate and emits first light in a first direction that is a direction perpendicular to the first plane,
a second semiconductor laser light source that is provided on the first plane and emits second light in the first direction,
a first mirror that reflects the first light emitted from the first semiconductor laser light source in the first direction,
a second mirror that transmits the first light reflected by the first mirror in a second direction different from the first direction and reflects the second light emitted from the second semiconductor laser light source in the second direction, and
a first condensing optical system that is provided between the first semiconductor laser light source and the first mirror, and a second condensing optical system that is provided between the second semiconductor laser light source and the second mirror,
in which a radiation angle of the first light emitted from the first semiconductor laser light source is smaller than a radiation angle of the second light emitted from the second semiconductor laser light source,
a distance between the first semiconductor laser light source and a principal point of the first condensing optical system is greater than a distance between the second semiconductor laser light source and a principal point of the second condensing optical system, and
an optical path length from the first semiconductor laser light source to the second mirror is greater than an optical path length from the second semiconductor laser light source to the second mirror.

According to an aspect of the present disclosure, a laser processing machine includes the laser module.

### BRIEF DESCRIPTION OF THE DRAWINGS

FIG. 1 is a diagram schematically showing a laser module according to the present embodiment.

FIG. 2 is a diagram schematically showing the laser module according to the present embodiment.

FIG. 3 is a cross-sectional view schematically showing a first semiconductor laser light source of the laser module according to the present embodiment.

FIG. 4 is a diagram schematically showing a laser module according to a first modification example of the present embodiment.

FIG. 5 is a diagram schematically showing the laser module according to the first modification example of the present embodiment.

FIG. 6 is a diagram schematically showing the laser module according to the first modification example of the present embodiment.

FIG. 7 is a perspective view schematically showing a laser module according to a second modification example of the present embodiment.

FIG. 8 is a diagram schematically showing a laser module according to a third modification example of the present embodiment.

FIG. 9 is a diagram schematically showing the laser module according to the third modification example of the present embodiment.

FIG. 10 is a diagram schematically showing a laser module according to a fourth modification example of the present embodiment.

FIG. 11 is a diagram schematically showing the laser module according to the fourth modification example of the present embodiment.

FIG. 12 is a diagram schematically showing a laser processing machine according to the present embodiment.

FIG. 13 is a diagram showing a simulation.

FIG. 14 is a table showing a simulation.

### DESCRIPTION OF EMBODIMENTS

Preferred embodiment of the present disclosure will be described in detail below with reference to the drawings. The embodiments to be described below do not unduly limit the content of the present disclosure described in the claims. In addition, not all the configurations described below are essential constituent elements of the present disclosure.

### 1. LASER MODULE

### 1.1. Overall Configuration

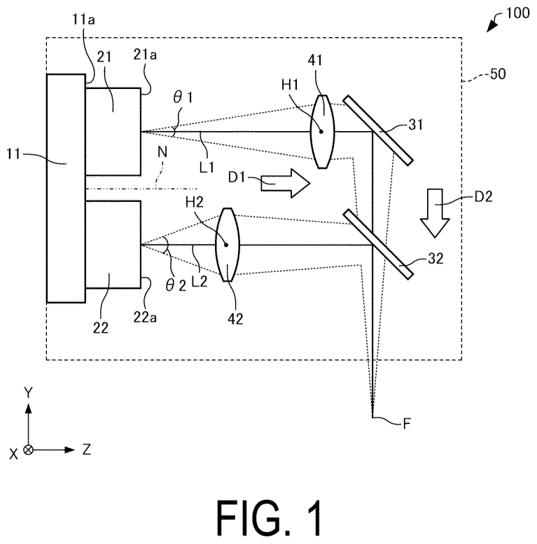

First, a laser module according to the present embodiment will be described with reference to the drawings. FIG. 1 is a diagram schematically showing a laser module 100 according to the present embodiment. An X-axis, a Y-axis, and a Z-axis are shown in FIG. 1 as three axes orthogonal to each other.

As shown in FIG. 1, the laser module 100 includes, for example, a first substrate 11, a first semiconductor laser light source 21, a second semiconductor laser light source 22, a first mirror 31, a second mirror 32, a first condensing optical system 41, a second condensing optical system 42, and a housing 50. For convenience, FIG. 1 shows the housing 50 in a see-through state.

The first substrate 11 supports the first semiconductor laser light source 21 and the second semiconductor laser light source 22. The first substrate 11 includes a first plane 11a. The first plane 11a is a flat surface. In the example shown in the drawing, a perpendicular line N of the first plane 11a is parallel to the Z axis. The first substrate 11 is, for example, a copper substrate or a silicon substrate. The first substrate 11 radiates heat generated by the semiconductor laser light sources 21 and 22.

The first semiconductor laser light source 21 is provided on the first plane 11a of the first substrate 11. The first semiconductor laser light source 21 is provided, for example, directly on the first plane 11a. The first semiconductor laser light source 21 includes an emission surface 21a that emits light. In the example shown in the drawing, the emission surface 21a is parallel to the first plane 11a. The emission surface 21a is the surface of the first semiconductor laser light source 21 opposite to the first substrate 11.

The first semiconductor laser light source 21 emits first light L1 in a first direction D1, which is the direction of the perpendicular line N. In the example shown in the drawing, the first direction D1 is a +Z-axis direction. Here, “emitting light in a direction A” means emitting light so that the optical axis of the light is in the direction A. Similarly, “transmitting light in the direction A” and “reflecting light in the direction A” mean transmitting and reflecting light so that the optical axis of the light is in the direction A, respectively. The “optical axis of light” means a beam of light passing through the center of the condensing optical system in a luminous flux.

The second semiconductor laser light source 22 is provided on the first plane 11a of the first substrate 11. The second semiconductor laser light source 22 is provided, for example, directly on the first plane 11a. In the example shown in the drawing, the semiconductor laser light sources 21 and 22 are aligned in the Y-axis direction. The emission surface 21a of the first semiconductor laser light source 21 and an emission surface 22a of the second semiconductor laser light source 22 are located on the same plane. The second semiconductor laser light source 22 emits second light L2 in the first direction D1.

A radiation angle θ1 of the first light L1 emitted from the first semiconductor laser light source 21 is smaller than a radiation angle θ2 of the second light L2 emitted from the second semiconductor laser light source 22. The semiconductor laser light sources 21 and 22 are, for example, photonic crystal surface emitting lasers (PCSELs). In the semiconductor laser light sources 21 and 22, the radiation angles θ1 and 02 can be adjusted by composite modulation by adjusting the arrangement of the photonic crystals, and the like.

The first mirror 31 reflects the first light L1, which is emitted from the first semiconductor laser light source 21 in the first direction D1, in the second direction D2. The second direction D2 is a direction different from the first direction D1. The first direction D1 and the second direction D2 are orthogonal to each other. In the example shown in the drawing, the second direction D2 is a −Y axis direction. The first mirror 31 bends the first light L1 by 90 degrees. Specifically, the first mirror 31 reflects the first light L1 condensed by the first condensing optical system 41.

The second mirror 32 transmits the first light L1 reflected by the first mirror 31 in the second direction D2, and reflects the second light L2, which is emitted from the second semiconductor laser light source 22 in the first direction D1, in the second direction D2. Then, the second mirror 32 multiplexes the first light L1 and the second light L2. The second mirror 32 bends the second light L2 by 90 degrees. Specifically, the second mirror 32 reflects the second light L2 condensed by the second condensing optical system 42. An optical path length from the first semiconductor laser light source 21 to the second mirror 32 is longer than an optical path length from the second semiconductor laser light source 22 to the second mirror 32.

The second mirror 32 is, for example, a polarization beam combiner (PBC). For example, the semiconductor laser light sources 21 and 22, which are PCSELs, can adjust the polarization directions of the light L1 and the light L2, respectively, by composite modulation. The light L1 and the light L2 have different polarization directions. For example, the first light L1 is P-polarized light, and the second light L2 is S-polarized light. In the example shown in the drawing, the mirrors 31 and 32 are aligned in the Y-axis direction. The light L1 and the light L2 are incident on the second mirror 32 as light beams with different polarization directions. The light L1 and the light L2 have the same polarization direction at a point in time when they are emitted from the semiconductor laser light sources 21 and 22, respectively, but may have different polarization directions at a point in time when they are incident on the second mirror 32.

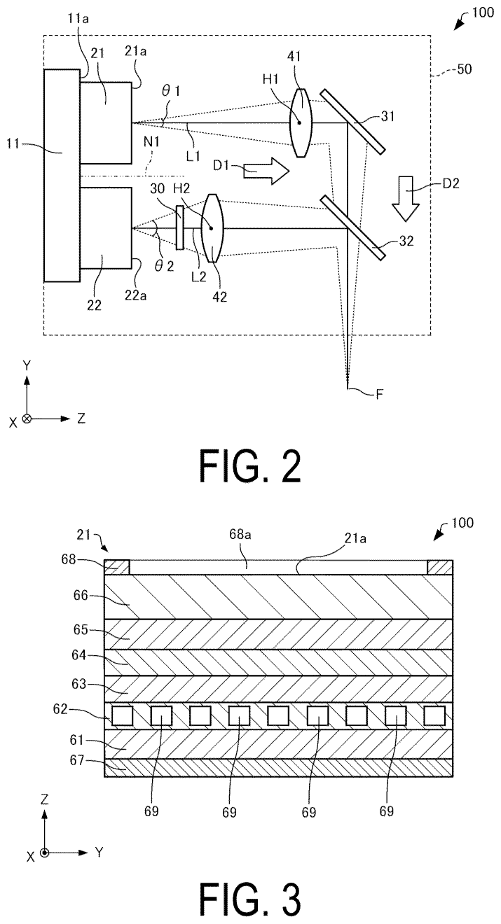

The first light L1 emitted from the first semiconductor laser light source 21 and the second light L2 emitted from the second semiconductor laser light source 22 may have the same polarization direction. The light L1 and the light L2 may be, for example, P-polarized light. In this case, as shown in FIG. 2, a λ/2 plate 30 is provided between the second semiconductor laser light source 22 and the second condensing optical system 42. The λ/2 plate 30 converts the P-polarized second light L2 emitted from the second semiconductor laser light source 22 into S-polarized light. Thereby, the second mirror 32 can multiplex the first light L1 emitted from the first semiconductor laser light source 21 and the second light L2 emitted from the second semiconductor laser light source 22.

However, when the semiconductor laser light sources 21 and 22 are PCSELs, the polarization of the light L1 and the light L2 can be adjusted by composite modulation without using the λ/2 plate 30, which allows the number of parts to be reduced, making it possible to achieve miniaturization and cost reduction.

As shown in FIG. 1, the first condensing optical system 41 is provided between the first semiconductor laser light source 21 and the first mirror 31. The first condensing optical system 41 condenses the first light L1 emitted from the first semiconductor laser light source 21 at a condensing point F. The second condensing optical system 42 is provided between the second semiconductor laser light source 22 and the second mirror 32. The second condensing optical system 42 condenses the second light L2 emitted from the second semiconductor laser light source 22 at a condensing point F. The condensing optical systems 41 and 42 are condenser lenses. In the example shown in the drawing, the light condensing optical systems 41 and 42 are convex lenses. The condensing point F is an imaging point of each of the light condensing optical systems 41 and 42. At the condensing point F, magnifications of a light source image formed by the first light L1 and a light source image formed by the second light L2 are not the same. However, with the PCSEL, the light source image can be made small, and thus the influence of magnification is negligible.

A distance between the first semiconductor laser light source 21 and a principal point H1 of the first condensing optical system 41 is greater than a distance between the second semiconductor laser light source 22 and a principal point H2 of the second condensing optical system 42. Specifically, a distance along an optical path between the first semiconductor laser light source 21 and the principal point H1 of the first condensing optical system 41 is greater than a distance along an optical path between the second semiconductor laser light source 22 and the principal point H2 of the second condensing optical system 42. Furthermore, as described above, the radiation angle θ1 of the first light L1 is smaller than the radiation angle θ2 of the second light L2. For this reason, in the laser module 100, an effective diameter of the first light L1 in the first condensing optical system 41 and an effective diameter of the second light L2 in the second condensing optical system 42 can be made the same. Thereby, the light L1 and the light L2 can be condensed such that condensing positions and condensing angles thereof are aligned at the condensing point F. In the present disclosure, when the term “principal point” is simply used, it refers to a front principal point when the light source side is an object side. The front principal point is also referred to as an object side principal point.

A lens surface of the first condensing optical system 41 and a lens surface of the second condensing optical system 42 have, for example, different curvatures. A distance along an optical path between the principal point H1 of the first condensing optical system 41 and the condensing point F and a distance along an optical path between the principal point H2 of the second condensing optical system 42 and the condensing point F may be the same or different.

The housing 50 accommodates the first substrate 11, the semiconductor laser light sources 21 and 22, the mirrors 31 and 32, and the condensing optical systems 41 and 42. The shape and material of the housing 50 are not particularly limited. Although not shown in the drawing, the housing 50 includes a window portion that allows the light L1 and the light L2 to pass therethrough. The housing 50 can facilitate handling of the laser module 100.

### 1.2 Configuration of Semiconductor Laser Light Source

FIG. 3 is a cross-sectional view schematically showing the first semiconductor laser light source 21. As shown in FIG. 3, the first semiconductor laser light source 21 includes, for example, a first semiconductor layer 61, a first guide layer 62, a quantum well layer 63, a second guide layer 64, a second semiconductor layer 65, a transparent substrate 66, a first electrode 67, and a second electrode 68. The first semiconductor laser light source 21 and the second semiconductor laser light source 22 basically have the same structure. Thus, the following description of the first semiconductor laser light source 21 can be applied to the description of the second semiconductor laser light source 22.

The first semiconductor layer 61 is provided between the first electrode 67 and the first guide layer 62. The first semiconductor layer 61 is a semiconductor layer of a first conductivity type. The first semiconductor layer 61 is, for example, a p-type semiconductor layer doped with Mg.

The first guide layer 62 is provided between the first semiconductor layer 61 and the quantum well layer 63. The first guide layer 62 has, for example, a semiconductor superlattice (SL) structure configured with a GaN layer and an InGaN layer which are an i-type and not intentionally doped with impurities. The numbers of the GaN layers and the InGaN layers configuring the first guide layer 62 are not particularly limited.

An opening 69 is formed in the first guide layer 62. The opening 69 is, for example, a hole. The width of the opening 69 is, for example, 50 nm or more and 500 nm or less. A plurality of openings 69 are formed. The plurality of openings 69 are arranged periodically when viewed from the Z-axis direction. The plurality of openings 69 are arranged, for example, in a regular triangular lattice shape or a square lattice shape. The plurality of openings 69 can exhibit a photonic crystal effect.

The quantum well layer 63 is provided between the first guide layer 62 and the second guide layer 64. The quantum well layer 63 generates light when a current is injected thereinto. The quantum well layer 63 includes, for example, a well layer and a barrier layer. The well layer and the barrier layer are i-type semiconductor layers which are not doped with impurities intentionally. The well layer is, for example, an InGaN layer. The barrier layer is, for example, a GaN layer. The quantum well layer 63 has a multiple quantum well (MQW) structure configured with the well layer and the barrier layer.

The numbers of the well layers and the barrier layers configuring the quantum well layer 63 are not particularly limited. For example, only one well layer may be provided, and in this case, the quantum well layer 63 has a single quantum well (SQW) structure.

The second guide layer 64 is provided between the quantum well layer 63 and the second semiconductor layer 65. The second guide layer 64 has, for example, an SL structure configured with a GaN layer and an InGaN layer which are an i-type and not intentionally doped with impurities. The numbers of the GaN layers and the InGaN layers configuring the second guide layer 64 are not particularly limited. The first guide layer 62 and the second guide layer 64 have a function of increasing a light confinement coefficient of the first semiconductor laser light source 21. Although not shown in the drawing, the plurality of openings 69 may be formed in the second guide layer 64 instead of in the first guide layer 62.

The second semiconductor layer 65 is provided between the quantum well layer 63 and the transparent substrate 66. The second semiconductor layer 65 is a semiconductor layer of a second conductivity type different from the first conductivity type. The second semiconductor layer 65 is, for example, an n-type GaN layer doped with Si. The first semiconductor layer 61 and the second semiconductor layer 65 are cladding layers that have a function of confining light in the quantum well layer 63.

In the first semiconductor laser light source 21, a pin diode is formed by the p-type first semiconductor layer 61, the i-type quantum well layer 63 and guide layers 62 and 64 that are not intentionally doped with impurities, and the n-type second semiconductor layer 65. In the first semiconductor laser light source 21, when a forward bias voltage of the pin diode is applied between the first electrode 67 and the second electrode 68, a current is injected into the quantum well layer 63, causing recombination of electrons and holes in the quantum well layer 63. This recombination causes light emission. The light generated in the quantum well layer 63 propagates in the in-plane direction, forms a standing wave by the photonic crystal effect due to the plurality of openings 69, receives a gain in the quantum well layer 63, and performs laser oscillation. Then, the first semiconductor laser light source 21 emits diffracted light as laser light.

The transparent substrate 66 is provided between the second semiconductor layer 65 and the second electrode 68. The transparent substrate 66 transmits light generated in the quantum well layer 63. The transparent substrate 66 is, for example, an n-type semiconductor substrate doped with Si.

The first electrode 67 is provided on the side of the first semiconductor layer 61 opposite to the first guide layer 62. The first semiconductor layer 61 may be in ohmic contact with the first electrode 67. The first electrode 67 is electrically coupled to the first semiconductor layer 61. The first electrode 67 is formed, for example, by stacking a Ni layer and an Au layer in this order from the first semiconductor layer 61 side. The first electrode 67 is one of the electrodes for injecting a current into the quantum well layer 63.

The second electrode 68 is provided on the side of the transparent substrate 66 opposite to the second semiconductor layer 65. The transparent substrate 66 may be in ohmic contact with the second electrode 68. The second electrode 68 is electrically coupled to the second semiconductor layer 65 via the transparent substrate 66. The second electrode 68 is formed, for example, by stacking a Cr layer, a Ni layer, and an Au layer in this order from the transparent substrate 66 side. The second electrode 68 is the other electrode for injecting a current into the quantum well layer 63.

A through hole 68a is formed in the second electrode 68. Light generated in the quantum well layer 63 is emitted through the through hole 68a. The area of the transparent substrate 66 exposed by the through hole 68a configures the emission surface 21a.

In a method of manufacturing the first semiconductor laser light source 21, the semiconductor layers 61 and 65, the guide layers 62 and 64, and the quantum well layer 63 are formed by epitaxial growth such as a metal organic chemical vapor deposition (MOCVD) method or a molecular beam epitaxy (MBE) method. The opening 69 is formed, for example, by patterning the first guide layer 62 using an electron beam lithography device. The electrodes 67 and 68 are formed by a sputtering method, a vacuum deposition method, a chemical vapor deposition (CVD) method, or the like. The formed first semiconductor laser light source 21 is, for example, junction-down mounted with the first electrode 67 side facing the first substrate 11 shown in FIG. 1.

### 1.3. Effects

The laser module 100 includes the first substrate 11, the first semiconductor laser light source 21 provided on the first plane 11a of the first substrate 11 and emitting the first light L1 in the first direction D1 that is the direction of the perpendicular line N of the first plane 11a, the second semiconductor laser light source 22 provided on the first plane 11a and emitting the second light L2 in the first direction D1, the first mirror 31 reflecting the first light L1 emitted from the first semiconductor laser light source 21 in the first direction D1, the second mirror 32 transmitting the first light L1 reflected by the first mirror 31 in the second direction D2 different from the first direction D1 and reflecting the second light L2 emitted from the second semiconductor laser light source 22 in the second direction D2, the first condensing optical system 41 provided between the first semiconductor laser light source 21 and the first mirror 31, and the second condensing optical system 42 provided between the second semiconductor laser light source 22 and the second mirror 32. The radiation angle θ1 of the first light L1 emitted from the first semiconductor laser light source 21 is smaller than the radiation angle θ2 of the second light L2 emitted from the second semiconductor laser light source 22. The distance between the first semiconductor laser light source 21 and the principal point H1 of the first condensing optical system 41 is greater than the distance between the second semiconductor laser light source 22 and the principal point H2 of the second condensing optical system 42. The optical path length from the first semiconductor laser light source 21 to the second mirror 32 is greater than the optical path length from the second semiconductor laser light source 22 to the second mirror 32.

For this reason, in the laser module 100, the positions of the first semiconductor laser light source 21 and the second semiconductor laser light source 22 can be adjusted by adjusting the position of the first substrate 11. Thus, the positions of the semiconductor laser light sources 21 and 22 can be easily adjusted. Furthermore, the semiconductor laser light sources 21 and 22 are easily mounted. Furthermore, since heat generated by the semiconductor laser light sources 21 and 22 can be radiated by one first substrate 11, temperature characteristics of the semiconductor laser light sources 21 and 22 can be made uniform. Thereby, it is possible to improve reliability and stability. Furthermore, temperature control of the semiconductor laser light sources 21 and 22 can be easily performed. Furthermore, a high output can be maintained by adjusting the condensing optical systems 41 and 42 in response to changes over time in the semiconductor laser light sources 21 and 22.

Furthermore, in the laser module 100, the radiation angle θ1 of the first light L1 is smaller than the radiation angle θ2 of the second light L2, the distance between the first semiconductor laser light source 21 and the principal point H1 of the first condensing optical system 41 is greater than the distance between the second semiconductor laser light source 22 and the principal point H2 of the second condensing optical system 42, and the optical path length from the first semiconductor laser light source 21 to the second mirror 32 is greater than the optical path length from the second semiconductor laser light source 22 to the second mirror 32, and thus the focusing positions and focusing angles of the light L1 and the light L2 can be aligned at the condensing point F. Thereby, it is possible to provide the laser module 100 with a high output and high beam parameter products (BPP).

Furthermore, in the laser module 100, the spread of light can be curbed compared to, for example, a case where a condensing optical system is provided at a rear stage of the second mirror. Thereby, it is possible to achieve miniaturization and cost reduction.

Furthermore, in the laser module 100, the effective diameter of the first light L1 in the first condensing optical system 41 and the effective diameter of the second light L2 in the second condensing optical system 42 can be made the same, and thus the diameters of the condensing optical systems 41 and 42 can be made the same. Thereby, it is possible to achieve miniaturization and cost reduction.

In the laser module 100, the first light L1 and the second light L2 are incident on the second mirror 32 as light beams with different polarization directions, and the second mirror 32 is a polarization beam combiner. For this reason, in the laser module 100, the first light L1 and the second light L2 can be multiplexed in the second mirror 32.

In the laser module 100, the first semiconductor laser light source 21 and the second semiconductor laser light source 22 are photonic crystal surface emitting lasers. For this reason, in the laser module 100, the radiation angle θ1 of the first light L1 and the radiation angle θ2 of the second light L2 can be adjusted by composite modulation.

In the above, the second mirror 32 is described as a polarization beam combiner, but the second mirror 32 may be a dichroic mirror. In this case, the first light L1 emitted from the first semiconductor laser light source 21 and the second light L2 emitted from the second semiconductor laser light source 22 have different wavelengths. For this reason, the second mirror 32, which is a dichroic mirror, can transmit the first light L1 and reflect the second light L2. For example, the wavelengths of the light L1 and the light L2 can be adjusted by composite modulation of the semiconductor laser light sources 21 and 22 which are PCSELs. By using the PCSELs, the wavelength of emitted light can be set finely. For example, the second mirror 32 transmits light with a wavelength equal to or shorter than a predetermined wavelength and reflects light with a wavelength longer than the predetermined wavelength. The first light L1 and the second light L2 may have the same polarization direction.

Although not shown in the drawing, a plurality of first condensing optical systems 41 may be provided between the first semiconductor laser light source 21 and the first mirror 31. In this case, the principal point of the first condensing optical system 41 is the principal point when the plurality of first condensing optical systems 41 are considered as a single virtual first condensing optical system 41. The same applies to the second condensing optical system 42.

Although not shown in the drawing, a condenser lens may be provided on the optical path from the second mirror 32 to the condensing point F.

### 2. MODIFICATION EXAMPLES

### 2.1. First Modification Example

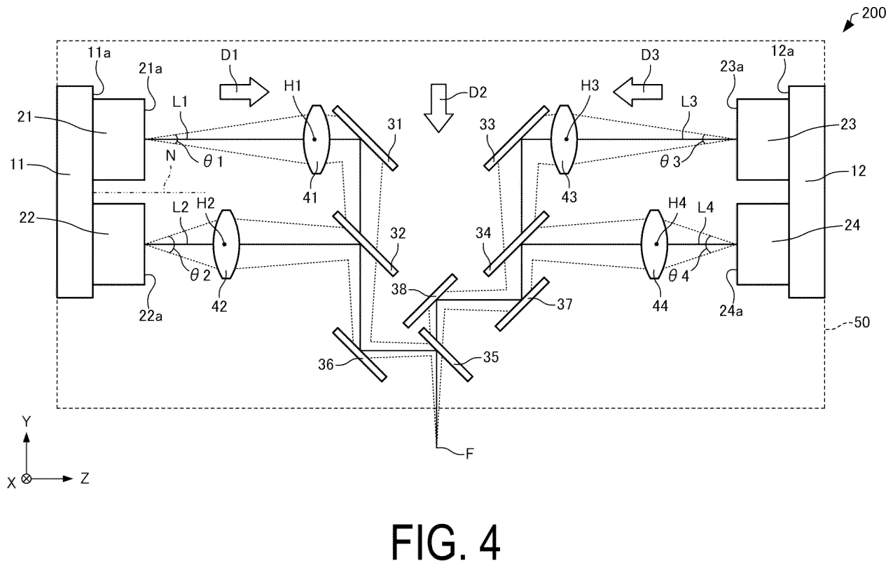

Next, a laser module according to a first modification example of the present embodiment will be described with reference to the drawings. FIG. 4 is a diagram schematically showing a laser module 200 according to the first modification example of the present embodiment.

Hereinafter, in the laser module 200 according to the first modification example of the present embodiment, members having the same functions as the components of the laser module 100 according to the present embodiment described above will be denoted by the same reference numerals, and detailed descriptions thereof will be omitted.

As shown in FIG. 4, the laser module 200 differs from the laser module 100 described above in that the laser module 200 includes a second substrate 12, a third semiconductor laser light source 23, a fourth semiconductor laser light source 24, a third mirror 33, a fourth mirror 34, a fifth mirror 35, mirrors 36, 37, and 38, a third condensing optical system 43, and a fourth condensing optical system 44. The second substrate 12, the semiconductor laser light sources 23 and 24, the mirrors 33, 34, 35, 36, 37, and 38, and the condensing optical systems 43 and 44 are accommodated in a housing 50.

The second substrate 12 is provided to face the first substrate 11. The second substrate 12 supports the third semiconductor laser light source 23 and the fourth semiconductor laser light source 24. The second substrate 12 includes a second plane 12a. The second plane 12a of the second substrate 12 faces the first plane 11a of the first substrate 11. The second plane 12a is a flat surface. The first plane 11a and the second plane 12a are, for example, parallel to each other. The material of the second substrate 12 is, for example, the same as the material of the first substrate 11. The second substrate 12 radiates heat generated by the semiconductor laser light sources 23 and 24.

The third semiconductor laser light source 23 is provided on the second plane 12a of the second substrate 12. The third semiconductor laser light source 23 is provided, for example, directly on the second plane 12a. The third semiconductor laser light source 23 is provided to face the first semiconductor laser light source 21. The third semiconductor laser light source 23 includes an emission surface 23a that emits light. The emission surface 23a and the second plane 12a are, for example, parallel to each other. The emission surface 23a is the surface of the third semiconductor laser light source 23 opposite to the second substrate 12.

The third semiconductor laser light source 23 emits third light L3 in a third direction D3. The third direction D3 is a direction along the perpendicular line N. The third direction D3 is a direction opposite to the first direction D1. In the example shown in the drawing, the third direction D3 is a −Z axis direction.

The fourth semiconductor laser light source 24 is provided on the second plane 12a of the second substrate 12. The fourth semiconductor laser light source 24 is provided, for example, directly on the second plane 12a. The fourth semiconductor laser light source 24 is provided to face the second semiconductor laser light source 22. In the example shown in the drawing, the semiconductor laser light sources 23 and 24 are aligned in the Y-axis direction. The emission surface 23a of the third semiconductor laser light source 23 and the emission surface 24a of the fourth semiconductor laser light source 24 are located on the same plane. The fourth semiconductor laser light source 24 emits fourth light L4 in the third direction D3.

A radiation angle θ3 of the third light L3 emitted from the third semiconductor laser light source 23 is smaller than a radiation angle θ4 of the fourth light L4 emitted from the fourth semiconductor laser light source 24. The semiconductor laser light sources 23 and 24 are, for example, PCSELs. In the semiconductor laser light sources 23 and 24, the radiation angles θ3 and θ4 can be adjusted by composite modulation by adjusting the arrangement of the photonic crystals, and the like. The radiation angles θ1 and θ3 are, for example, the same size. The radiation angles θ2 and θ4 are, for example, the same size.

The third mirror 33 reflects the third light L3, which is emitted from the third semiconductor laser light source 23 in the third direction D3, in the second direction D2.

The fourth mirror 34 transmits the third light L3, which is reflected by the third mirror 33, in the second direction D2, and reflects the fourth light L4, which is emitted from the fourth semiconductor laser light source 24 in the third direction D3, in the second direction D2. The fourth mirror 34 then multiplexes the third light L3 and the fourth light L4. An optical path length from the third semiconductor laser light source 23 to the fourth mirror 34 is longer than an optical path length from the fourth semiconductor laser light source 24 to the fourth mirror 34.

The fourth mirror 34 is, for example, a polarization beam combiner. For example, the semiconductor laser light sources 23 and 24, which are PCSELs, can adjust the polarization direction of the light L3 and the light L4, respectively, by composite modulation. The light L3 and the light L4 have different polarization directions. For example, the third light L3 is P-polarized light, and the fourth light L4 is S-polarized light. In the example shown in the drawing, the mirrors 33 and 34 are aligned in the Y-axis direction.

The mirror 36 reflects the light L1 and the light L2 from the second mirror 32 in the first direction D1. The mirror 37 reflects the light L3 and the light L4 from the fourth mirror 34 in the third direction D3. The mirror 38 reflects the light L3 and the light L4 from the mirror 37 in the second direction D2.

The fifth mirror 35 is a dichroic mirror. The first light L1 and the second light L2 are light with a first wavelength. The third light L3 and the fourth light L4 are light with a second wavelength different from the first wavelength. For this reason, the fifth mirror 35, which is a dichroic mirror, can reflect the light L1 and the light L2 and transmit the light L3 and the light L4. Specifically, the fifth mirror 35 reflects the light L1 and the light L2 from the second mirror 32 in the second direction D2, and transmits the light L3 and the light L4 from the fourth mirror 34 in the second direction D2. More specifically, the fifth mirror 35 reflects the light L1 and the light L2 reflected by the mirror 36 in the second direction D2, and transmits the light L3 and the light L4 reflected by the mirror 38 in the second direction D2. The fifth mirror 35 multiplexes the light L1 and the light L2 with the light L3 and the light L4.

The third condensing optical system 43 is provided between the third semiconductor laser light source 23 and the third mirror 33. The third condensing optical system 43 condenses the third light L3, which is emitted from the third semiconductor laser light source 23, at a condensing point F. The fourth condensing optical system 44 is provided between the fourth semiconductor laser light source 24 and the fourth mirror 34. The fourth condensing optical system 44 condenses the fourth light L4, which is emitted from the fourth semiconductor laser light source 24, at the condensing point F. The condensing optical systems 43 and 44 are condenser lenses. In the example shown in the drawing, the condensing optical systems 43 and 44 are convex lenses.

A distance between the third semiconductor laser light source 23 and a principal point H3 of the third condensing optical system 43 is greater than a distance between the fourth semiconductor laser light source 24 and a principal point H4 of the fourth condensing optical system 44. Furthermore, as described above, the radiation angle θ3 of the third light L3 is smaller than the radiation angle θ4 of the fourth light L4. For this reason, in the laser module 200, an effective diameter of the third light L3 in the third condensing optical system 43 can be made the same as an effective diameter of the fourth light L4 in the fourth condensing optical system 44. Furthermore, the effective diameter of the first light L1 in the first condensing optical system 41 can be made the same as the effective diameter of the third light L3 in the third condensing optical system 43. For this reason, the light beams L1, L2, L3, and L4 can be condensed at the condensing point F so that condensing positions and condensing angles thereof are aligned at the condensing point F.

A lens surface of the third condensing optical system 43 and a lens surface of the fourth condensing optical system 44 have, for example, different curvatures. A distance along an optical path between the principal point H3 of the third condensing optical system 43 and the condensing point F may be the same as or different from a distance along an optical path between the principal point H4 of the fourth condensing optical system 44 and the condensing point F. The light beams L1, L2, L3, and L4 emitted from the semiconductor laser light sources 21 and 22, 23, and 24 can be condensed at the condensing point F by the condensing optical systems 41 and 42, 43, and 44, respectively.

The laser module 200 includes the second substrate 12 provided to face the first substrate 11, the third semiconductor laser light source 23 provided on the second plane 12a of the second substrate 12 and emitting the third light L3 in the third direction D3 opposite to the first direction D1, the fourth semiconductor laser light source 24 provided on the second plane 12a and emitting the fourth light L4 in the third direction D3, the third mirror 33 reflecting the third light L3 emitted from the third semiconductor laser light source 23 in the third direction D3, the fourth mirror 34 transmitting the third light L3 reflected by the third mirror 33 in the second direction D2 and reflecting the fourth light L4 emitted from the fourth semiconductor laser light source 24 in the second direction D2, and the fifth mirror 35 reflecting the first light L1 and the second light L2 from the second mirror 32 in the second direction D2 and transmitting the third light L3 and the fourth light L4 from the fourth mirror 34 in the second direction D2.

For this reason, in the laser module 200, the first light L1, the second light L2, the third light L3, and the fourth light L4 can be multiplexed. For this reason, it is possible to achieve a high output.

In the laser module 200, the first light L1 and the second light L2 are light with a first wavelength, the third light L3 and the fourth light L4 are light with a second wavelength different from the first wavelength, and the fifth mirror 35 is a dichroic mirror. For this reason, in the laser module 200, the first light L1, the second light L2, the third light L3, and the fourth light L4 can be multiplexed in the fifth mirror 35.

The first light L1 emitted from the first semiconductor laser light source 21, the second light L2 emitted from the second semiconductor laser light source 22, the third light L3 emitted from the third semiconductor laser light source 23, and the fourth light L4 emitted from the fourth semiconductor laser light source 24 may have the same polarization direction. The light beams L1, L2, L3, and L4 may be, for example, S-polarized light.

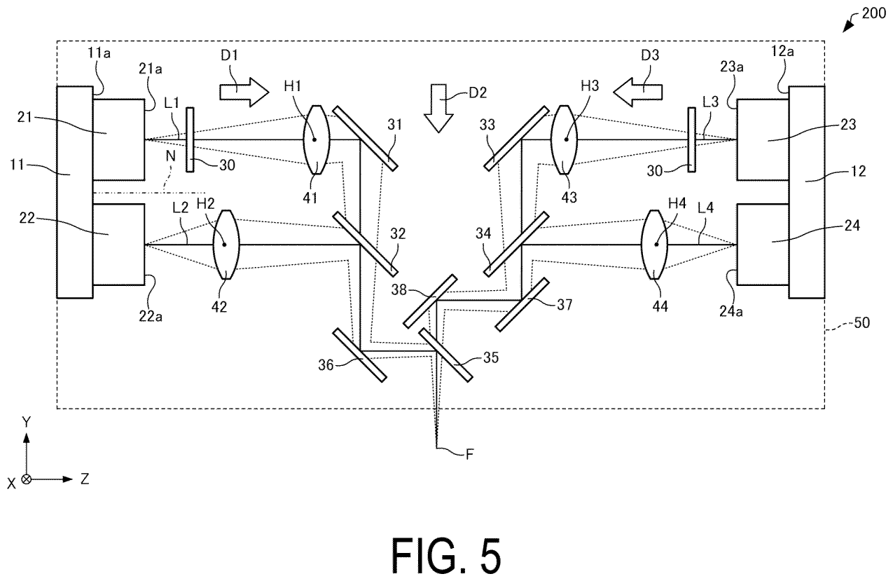

In this case, as shown in FIG. 5, a λ/2 plate 30 is provided on the optical path from the first semiconductor laser light source 21 to the first condensing optical system 41 and on the optical path from the third semiconductor laser light source 23 to the third condensing optical system 43. The λ/2 plate 30 converts the S-polarized first light L1 emitted from the first semiconductor laser light source 21 and the S-polarized third light L3 emitted from the third semiconductor laser light source 23 into P-polarized light. Thereby, the second mirror 32 can multiplex the first light L1 emitted from the first semiconductor laser light source 21 and the second light L2 emitted from the second semiconductor laser light source 22. Furthermore, the fourth mirror 34 can multiplex the third light L3 emitted from the third semiconductor laser light source 23 and the fourth light L4 emitted from the fourth semiconductor laser light source 24.

Although a case where the second mirror 32 and the fourth mirror 34 are polarization beam combiners, and the fifth mirror 35 is a dichroic mirror has been described above, the second mirror 32 and the fourth mirror 34 may be dichroic mirrors, and the fifth mirror 35 may be a polarization beam combiner.

In this case, the first light L1 and the third light L3 are light with a first wavelength, and the second light L2 and the fourth light L4 are light with a second wavelength different from the first wavelength. The light L1 and the light L2 are incident on the fifth mirror 35 as first polarized light, and the light L3 and the light L4 are incident on the fifth mirror 35 as second polarized light different from the first polarized light. The first polarized light may be S-polarized light, and the second polarized light may be P-polarized light. The semiconductor laser light sources 21, 22, 23, and 24 may emit light beams with different wavelengths.

However, semiconductor laser light sources that emit light beams with the same wavelength have the same temperature characteristics. For this reason, it is easier to perform temperature control when the semiconductor laser light sources 21 and 22 provided on the first substrate 11 emit light beams with the same wavelength, and the semiconductor laser light sources 23 and 24 provided on the second substrate 12 emit light beams with the same wavelength. Thereby, it is possible to achieve stability for the environment.

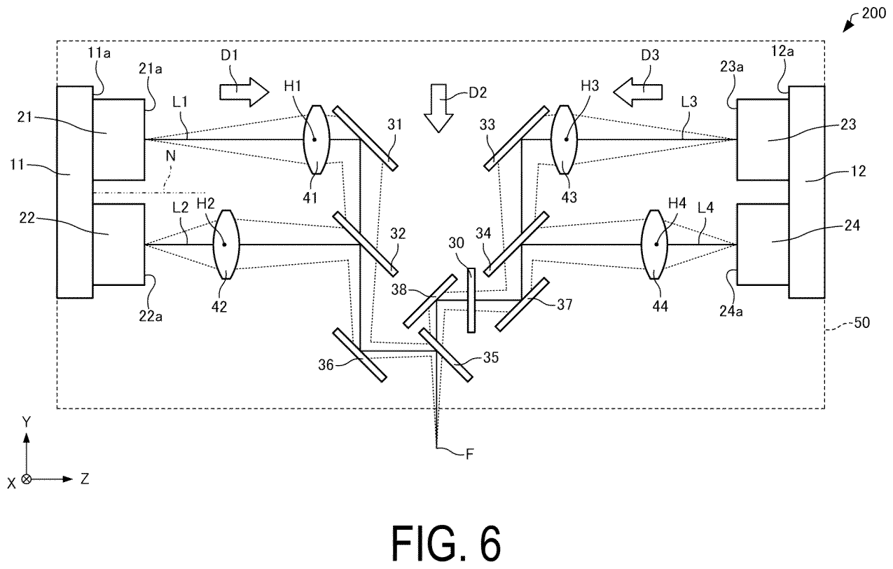

Furthermore, when the second mirror 32 and the fourth mirror 34 are dichroic mirrors and the fifth mirror 35 is a polarization beam combiner, the semiconductor laser light sources 21, 22, 23, and 24 emit first polarized light, and the λ/2 plate 30 may be provided on the optical path from the mirror 36 to the mirror 37 as shown in FIG. 6. Thereby, the light L3 and the light L4 emitted from the semiconductor laser light sources 23 and 24 can be converted from the first polarized light to the second polarized light. By disposing the fifth mirror 35, which is a polarization beam combiner, at a stage after the mirrors 32 and 34, which are dichroic mirrors, the number of polarization beam combiners can be reduced, making it possible to achieve cost reduction.

### 2.2. Second Modification Example

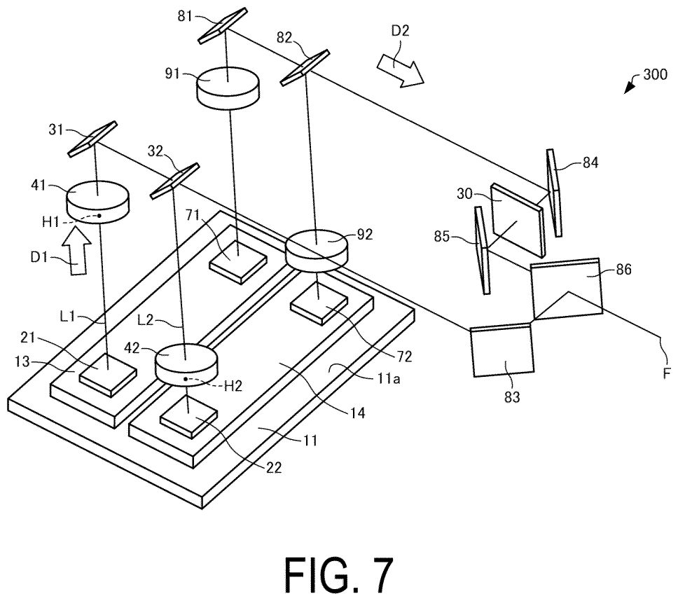

Next, a laser module according to a second modification example of the present embodiment will be described with reference to the drawings. FIG. 7 is a diagram schematically showing a laser module 300 according to the second modification example of the present embodiment.

Hereinafter, in the laser module 300 according to the second modification example of the present embodiment, members having the same functions as the components of the laser module 100 according to the present embodiment described above will be denoted by the same reference numerals, and detailed descriptions thereof will be omitted.

As shown in FIG. 7, the laser module 300 differs from the laser module 100 described above in that the laser module 300 includes substrates 13 and 14, semiconductor laser light sources 71 and 72, mirrors 81, 82, 83, 84, 85, and 86, and condensing optical systems 91 and 92. For convenience, FIG. 7 does not show the spread of light emitted from the semiconductor laser light sources 21, 22, 71, and 72.

The substrates 13 and 14 are provided on the first substrate 11. The material of the substrates 13 and 14 may be the same as or different from the material of the first substrate 11. The shapes of the substrates 13 and 14 may be the same or different. Providing the substrates 13 and 14 on the first substrate 11 can facilitate mounting and assembling. In addition, the substrates 13 and 14 do not necessarily have to be provided together on the first substrate 11.

The semiconductor laser light sources 21 and 71 are provided on the substrate 13. The semiconductor laser light sources 21 and 71 are provided on the first substrate 11 via the substrate 13. The semiconductor laser light sources 22 and 72 are provided on the substrate 14. The semiconductor laser light sources 22 and 72 are provided on the first substrate 11 via the substrate 14. The semiconductor laser light sources 71 and 72 emit light in the first direction D1. The optical axis of the light L1 emitted from the first semiconductor laser light source 21, the optical axis of the light L2 emitted from the second semiconductor laser light source 22, the optical axis of light emitted from the semiconductor laser light source 71, and the optical axis of light emitted from the semiconductor laser light source 72 are parallel to each other.

The semiconductor laser light sources 21 and 71 emit light beams with the same wavelength. The semiconductor laser light sources 22 and 72 emit light beams with the same wavelength. In the laser module 300, the semiconductor laser light sources 21 and 71 that emit light beams with the same wavelength are provided on the substrate 13, and thus temperature characteristics of the semiconductor laser light sources 21 and 71 can be made the same. Furthermore, the semiconductor laser light sources 22 and 72 that emit light beams with the same wavelength are provided on the substrate 14, and thus temperature characteristics of the semiconductor laser light sources 22 and 72 can be made the same. The semiconductor laser light sources 21 and 22 emit light beams with different wavelengths.

The semiconductor laser light sources 21, 22, 71, and 72 emit the same polarized light. The semiconductor laser light sources 21, 22, 71, and 72 emit, for example, S-polarized light.

A radiation angle of light emitted from the semiconductor laser light source 71 is, for example, the same as the radiation angle of the first light L1 of the first semiconductor laser light source 21. The semiconductor laser light source 71 has basically the same configuration as that of the first semiconductor laser light source 21.

A radiation angle of light emitted from the semiconductor laser light source 72 is, for example, the same as the radiation angle of the second light L2 of the second semiconductor laser light source 22. The semiconductor laser light source 72 has basically the same configuration as that of the second semiconductor laser light source 22.

The mirror 81 reflects light, which is emitted from the semiconductor laser light source 71 in the first direction D1, in the second direction D2.

The mirror 82 transmits light from the mirror 81 in the second direction D2 and reflects light, which is emitted from the semiconductor laser light source 72 in the first direction D1, in the second direction D2. The mirrors 32 and 82 are dichroic mirrors.

The mirror 83 reflects light from the second mirror 32 in a direction perpendicular to the first direction D1 and the second direction D2. The mirror 84 reflects light from the mirror 82 in a direction perpendicular to the first direction D1 and the second direction D2. The mirror 85 reflects light from the mirror 84 in the second direction D2. The λ/2 plate 30 is provided on an optical path from the mirror 84 to the mirror 85. Thereby, the light reflected by the mirror 84 is converted, for example, from S-polarized light to P-polarized light.

The mirror 86 reflects light reflected by the mirror 83 in the second direction D2, and transmits light reflected by the mirror 85 in the second direction D2. The mirror 86 is a polarization beam combiner.

The condensing optical system 91 is provided between the semiconductor laser light source 71 and the mirror 81. The condensing optical system 92 is provided between the semiconductor laser light source 72 and the mirror 82. The condensing optical systems 91 and 92 are, for example, condenser lenses. A distance between the semiconductor laser light source 71 and the principal point of the condensing optical system 91 is, for example, the same as a distance between the first semiconductor laser light source 21 and the principal point H1 of the first condensing optical system 41. A distance between the semiconductor laser light source 72 and the principal point of the condensing optical system 92 is, for example, the same as a distance between the second semiconductor laser light source 22 and the principal point H2 of the second condensing optical system 42.

In the laser module 300, light emitted from the semiconductor laser light sources 21, 22, 71, and 72 can be condensed at the condensing point F by the condensing optical systems 41 and 42, 91, and 92, respectively. For this reason, it is possible to achieve a high output.

### 2.3. Third Modification Example

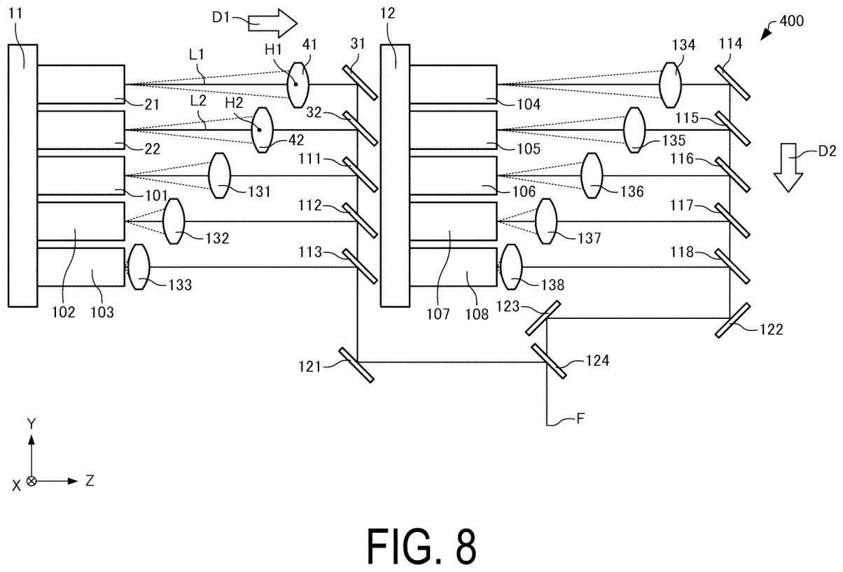

Next, a laser module according to a third modification example of the present embodiment will be described with reference to the drawings. FIG. 8 is a diagram schematically showing a laser module 400 according to the third modification example of the present embodiment.

Hereinafter, in the laser module 400 according to the third modification example of the present embodiment, members having the same functions as the components of the laser module 100 according to the present embodiment described above will be denoted by the same reference numerals, and detailed descriptions thereof will be omitted.

As shown in FIG. 8, the laser module 400 differs from the laser module 100 described above in that the laser module 400 includes semiconductor laser light sources 101, 102, 103, 104, 105, 106, 107, and 108, mirrors 111, 112, 113, 114, 115, 116, 117, 118, 121, 122, 123, and 124, and condensing optical systems 131, 132, 133, 134, 135, 136, 137, and 138.

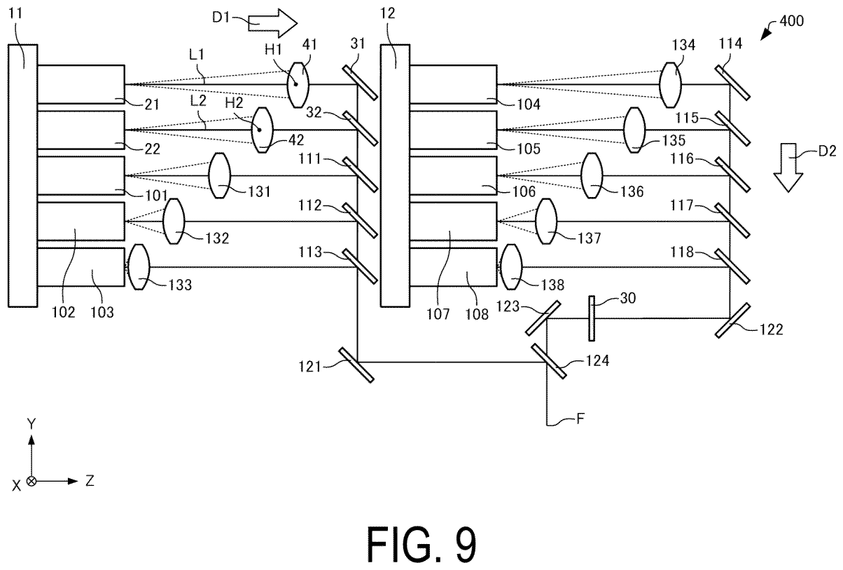

For convenience, in FIG. 8, a part of the spread of light is omitted in an optical path from the semiconductor laser light source to the condensing point F. The same applies to FIGS. 9 to 11 to be described later.

The semiconductor laser light sources 101, 102, and 103 are provided on the first substrate 11. In the example shown in the drawing, the semiconductor laser light sources 21, 22, 101, 102, and 103 are arranged in this order in the Y-axis direction. The semiconductor laser light sources 101, 102, and 103 emit light in the first direction D1. The optical axis of the light L1 emitted from the first semiconductor laser light source 21, the optical axis of the light L2 emitted from the second semiconductor laser light source 22, the optical axis of light emitted from the semiconductor laser light source 101, the optical axis of light emitted from the semiconductor laser light source 102, and the optical axis of light emitted from the semiconductor laser light source 103 are parallel to each other.

A radiation angle of light emitted from the semiconductor laser light source 101 is greater than a radiation angle of light emitted from the second semiconductor laser light source 22. A radiation angle of light emitted from the semiconductor laser light source 102 is greater than a radiation angle of light emitted from the semiconductor laser light source 101. A radiation angle of light emitted from the semiconductor laser light source 103 is greater than a radiation angle of light emitted from the semiconductor laser light source 102.

The semiconductor laser light sources 21, 22, 101, 102, and 103 emit light beams with different wavelengths. The semiconductor laser light sources 21, 22, 101, 102, and 103 emit the same polarized light. The semiconductor laser light sources 21, 22, 101, 102, and 103 emit, for example, S-polarized light.

The semiconductor laser light sources 104, 105, 106, 107, and 108 are provided on the second substrate 12. In the example shown in the drawing, the semiconductor laser light sources 104, 105, 106, 107, and 108 are arranged in this order in the Y-axis direction. The semiconductor laser light sources 104, 105, 106, 107, and 108 emit light in the first direction D1. The optical axis of light emitted from the semiconductor laser light source 104, the optical axis of light emitted from the semiconductor laser light source 105, the optical axis of light emitted from the semiconductor laser light source 106, the optical axis of light emitted from the semiconductor laser light source 107, and the optical axis of light emitted from the semiconductor laser light source 108 are parallel to each other.

A radiation angle of light emitted from the semiconductor laser light source 104 is the same as, for example, the radiation angle of the light emitted from the first semiconductor laser light source 21. A radiation angle of light emitted from the semiconductor laser light source 105 is the same as, for example, the radiation angle of the light emitted from the second semiconductor laser light source 22. A radiation angle of light emitted from the semiconductor laser light source 106 is the same as, for example, the radiation angle of the light emitted from the semiconductor laser light source 101. A radiation angle of light emitted from the semiconductor laser light source 107 is the same as, for example, the radiation angle of the light emitted from the semiconductor laser light source 102. A radiation angle of light emitted from the semiconductor laser light source 108 is the same as, for example, the radiation angle of the light emitted from the semiconductor laser light source 103.

The semiconductor laser light sources 104, 105, 106, 107, and 108 emit light beams having different wavelengths. The semiconductor laser light sources 104, 105, 106, 107, and 108 emit the same polarized light. The semiconductor laser light sources 104, 105, 106, 107, and 108 emit, for example, P-polarized light. The semiconductor laser light sources 101, 102, 103, 104, 105, 106, 107, and 108 are, for example, PCSELS.

The wavelength of the first light L1 emitted from the first semiconductor laser light source 21 and the wavelength of the light emitted from the semiconductor laser light source 104 may be the same. The wavelength of the second light L2 emitted from the second semiconductor laser light source 22 and the wavelength of the light emitted from the semiconductor laser light source 105 may be the same. The wavelength of the light emitted from the semiconductor laser light source 101 and the wavelength of the light emitted from the semiconductor laser light source 106 may be the same. The wavelength of the light emitted from the semiconductor laser light source 102 and the wavelength of the light emitted from the semiconductor laser light source 107 may be the same. The wavelength of the light emitted from the semiconductor laser light source 103 and the wavelength of the light emitted from the semiconductor laser light source 108 may be the same.

The mirror 111 transmits the light L1 and the light L2 from the second mirror 32 in the second direction D2, and reflects light, which is emitted from the semiconductor laser light source 101 in the first direction D1, in the second direction D2.

The mirror 112 transmits light from the mirror 111 in the second direction D2, and reflects light, which is emitted from the semiconductor laser light source 102 in the first direction D1, in the second direction D2.

The mirror 113 transmits light from the mirror 112 in the second direction D2, and reflects light, which is emitted from the semiconductor laser light source 103 in the first direction D1, in the second direction D2. The mirrors 32, 111, 112, and 113 are dichroic mirrors.

The mirror 114 reflects light, which is emitted from the semiconductor laser light source 104 in the first direction D1, in the second direction D2.

The mirror 115 transmits light, which is reflected by the mirror 114, in the second direction D2, and reflects light, which is emitted from the semiconductor laser light source 105 in the first direction D1, in the second direction D2.

The mirror 116 transmits light from the mirror 115 in the second direction D2, and reflects light, which is emitted from semiconductor laser light source 106 in the first direction D1, in the second direction D2.

The mirror 117 transmits light from the mirror 116 in the second direction D2, and reflects light, which is emitted from semiconductor laser light source 107 in the first direction D1, in the second direction D2.

The mirror 118 transmits light from the mirror 117 in the second direction D2, and reflects light, which is emitted from semiconductor laser light source 108 in the first direction D1, in the second direction D2. The mirrors 114, 115, 116, 117, and 118 are dichroic mirrors.

The mirror 121 reflects light from the mirror 113 in the first direction D1. The mirror 122 reflects light from the mirror 118 in a direction opposite to the first direction D1. The mirror 123 reflects light from the mirror 122 in the second direction D2.

The mirror 124 reflects light from the mirror 121 in the second direction D2 and transmits light from the mirror 123 in the second direction D2. The mirror 124 is a polarization beam combiner.

The condensing optical system 131 is provided between the semiconductor laser light source 101 and the mirror 111. A distance between the semiconductor laser light source 101 and the principal point of the condensing optical system 131 is smaller than a distance between the second semiconductor laser light source 22 and the principal point H2 of the second condensing optical system 42.

The condensing optical system 132 is provided between the semiconductor laser light source 102 and the mirror 112. A distance between the semiconductor laser light source 102 and the principal point of the condensing optical system 132 is smaller than a distance between the semiconductor laser light source 101 and the principal point of the condensing optical system 131.

The condensing optical system 133 is provided between the semiconductor laser light source 103 and the mirror 113. A distance between the semiconductor laser light source 103 and the principal point of the condensing optical system 133 is smaller than a distance between the semiconductor laser light source 102 and the principal point of the condensing optical system 132.

The condensing optical system 134 is provided between the semiconductor laser light source 104 and the mirror 114. A distance between the semiconductor laser light source 104 and the principal point of the condensing optical system 134 is, for example, the same as a distance between the first semiconductor laser light source 21 and the principal point H 1 of the first condensing optical system 41.

The condensing optical system 135 is provided between the semiconductor laser light source 105 and the mirror 115. A distance between the semiconductor laser light source 105 and the principal point of the condensing optical system 135 is, for example, the same as a distance between the second semiconductor laser light source 22 and the principal point H2 of the second condensing optical system 42.

The condensing optical system 136 is provided between the semiconductor laser light source 106 and the mirror 116. A distance between the semiconductor laser light source 106 and the principal point of the condensing optical system 136 is, for example, the same as a distance between the semiconductor laser light source 101 and the principal point of the condensing optical system 131.

The condensing optical system 137 is provided between the semiconductor laser light source 107 and the mirror 117. A distance between the semiconductor laser light source 107 and the principal point of the condensing optical system 137 is, for example, the same as a distance between the semiconductor laser light source 102 and the principal point of the condensing optical system 132.

The condensing optical system 138 is provided between the semiconductor laser light source 108 and the mirror 118. A distance between the semiconductor laser light source 108 and the principal point of the condensing optical system 138 is, for example, the same as a distance between the semiconductor laser light source 103 and the principal point of the condensing optical system 133.

The condensing optical systems 131, 132, 133, 134, 135, 136, 137, and 138 are, for example, condenser lenses. In the example shown in the drawing, the condensing optical systems 131, 132, 133, 134, 135, 136, 137, and 138 are convex lenses. The effective diameters of light in the condensing optical systems 41, 42, 131, 132, 133, 134, 135, 136, 137, and 138 may be the same.

In the laser module 400, light beams emitted from the semiconductor laser light sources 21, 22, 101, 102, 103, 104, 105, 106, 107, and 108 can be condensed at the condensing point F by the condensing optical systems 41, 42, 131, 132, 133, 134, 135, 136, 137, and 138, respectively. For this reason, it is possible to achieve a high output.

The semiconductor laser light sources 104, 105, 106, 107, and 108 may emit, for example, the same polarized light as the semiconductor laser light sources 21, 22, 101, 102, and 103. In this case, as shown in FIG. 9, the λ/2 plate 30 is provided in an optical path from the mirror 122 to the mirror 123. Thereby, the light emitted from the semiconductor laser light sources 104, 105, 106, 107, and 108 can be converted, for example, from S-polarized light to P-polarized light.

In addition, the number of semiconductor laser light sources and the number of mirrors are not particularly limited.

### 2-4. Fourth Modification Example

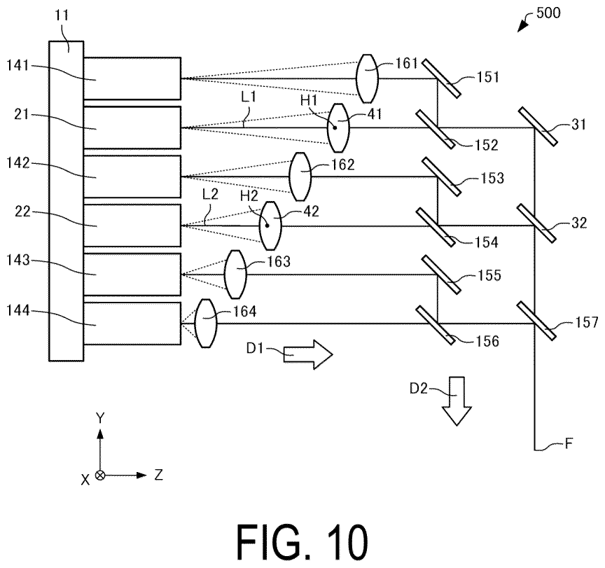

Next, a laser module according to a fourth modification example of the present embodiment will be described with reference to the drawings. FIG. 10 is a diagram schematically showing a laser module 500 according to the fourth modification example of the present embodiment.

Hereinafter, in the laser module 500 according to the fourth modification example of the present embodiment, members having the same functions as the components of the laser module 100 according to the present embodiment described above will be denoted by the same reference numerals, and detailed descriptions thereof will be omitted.

As shown in FIG. 10, the laser module 500 differs from the laser module 100 described above in that the laser module 500 includes semiconductor laser light sources 141, 142, 143, and 144, mirrors 151, 152, 153, 154, 155, 156, and 157, and condensing optical systems 161, 162, 163, and 164.

The semiconductor laser light sources 141, 142, 143, and 144 are provided on the first substrate 11. In the example shown in the drawing, the semiconductor laser light sources 141, 21, 142, 22, 143, and 144 are arranged in this order in the Y-axis direction. The semiconductor laser light sources 141, 142, 143, and 144 emit light in the first direction D1. The optical axis of the light L1 emitted from the first semiconductor laser light source 21, the optical axis of the light L2 emitted from the second semiconductor laser light source 22, the optical axis of the light emitted from the semiconductor laser light source 141, the optical axis of the light emitted from the semiconductor laser light source 142, the optical axis of the light emitted from the semiconductor laser light source 143, and the optical axis of the light emitted from the semiconductor laser light source 144 are parallel to each other.

A radiation angle of light emitted from the first semiconductor laser light source 21 is greater than a radiation angle of light emitted from the semiconductor laser light source 141. A radiation angle of light emitted from the semiconductor laser light source 142 is greater than a radiation angle of light emitted from the first semiconductor laser light source 21. A radiation angle of light emitted from the second semiconductor laser light source 22 is greater than a radiation angle of light emitted from the semiconductor laser light source 142. A radiation angle of light emitted from the semiconductor laser light source 143 is greater than a radiation angle of light emitted from the second semiconductor laser light source 22. A radiation angle of light emitted from the semiconductor laser light source 144 is greater than a radiation angle of light emitted from the semiconductor laser light source 143.

The semiconductor laser light sources 21 and 141 emit light beams with the same wavelength. The semiconductor laser light sources 22, 142 emit light beams with the same wavelength. The semiconductor laser light sources 143 and 144 emit light beams with the same wavelength. The semiconductor laser light sources 21 and 22, and 143 emit light beams with different wavelengths.

The semiconductor laser light sources 21, 22, and 144 emit first polarized light. The semiconductor laser light sources 21, 22, and 144 emit, for example, P-polarized light. The semiconductor laser light sources 141, 142, and 143 emit second polarized light different from the first polarized light. The semiconductor laser light sources 141, 142, and 143 emit, for example, S-polarized light. The semiconductor laser light sources 141, 142, 143, and 144 are, for example, PCSELs.

The mirror 151 reflects light, which is emitted from the semiconductor laser light source 141 in the first direction D1, in the second direction D2.

The mirror 152 transmits light, which is emitted from the first semiconductor laser light source 21 in the first direction D1, in the first direction D1, and reflects light reflected by the mirror 151 in the first direction D1. The mirror 152 is a polarization beam combiner.

The mirror 153 reflects light, which is emitted from the semiconductor laser light source 142 in the first direction D1, in the second direction D2.

The mirror 154 transmits light, which is emitted from the second semiconductor laser light source 22 in the first direction D1, in the first direction D1, and reflects light reflected by the mirror 153 in the first direction D1. The mirror 154 is a polarization beam combiner.

The mirror 155 reflects light, which is emitted from semiconductor laser light source 143 in the first direction D1, in the second direction D2.

The mirror 156 transmits light, which is emitted from semiconductor laser light source 144 in the first direction D1, in the first direction D1, and reflects light reflected by the mirror 155 in the first direction D1. The mirror 156 is a polarization beam combiner.

The first mirror 31 reflects light from the mirror 152 in the second direction D2.

The second mirror 32 transmits light from the first mirror 31 in the second direction D2 and reflects light from the mirror 154 in the second direction D2. The second mirror 32 is a dichroic mirror.

The mirror 157 transmits light from the second mirror 32 in the second direction D2, and reflects light from the mirror 156 in the second direction D2. The mirror 157 is a dichroic mirror.

The condensing optical system 161 is provided between the semiconductor laser light source 141 and the mirror 151.

The first condensing optical system 41 is provided between the first semiconductor laser light source 21 and the mirror 152. A distance between the first semiconductor laser light source 21 and the principal point H1 of the first condensing optical system 41 is smaller than a distance between the semiconductor laser light source 141 and the principal point of the condensing optical system 161.

The condensing optical system 162 is provided between the semiconductor laser light source 142 and the mirror 153. A distance between the semiconductor laser light source 142 and the principal point of the condensing optical system 162 is smaller than a distance between the first semiconductor laser light source 21 and the principal point H1 of the first condensing optical system 41.

The second condensing optical system 42 is provided between the second semiconductor laser light source 22 and the mirror 154. A distance between the second semiconductor laser light source 22 and the principal point H2 of the second condensing optical system 42 is smaller than a distance between the semiconductor laser light source 142 and the principal point of the condensing optical system 162.

The condensing optical system 163 is provided between the semiconductor laser light source 143 and the mirror 155. A distance between the semiconductor laser light source 143 and the principal point of the condensing optical system 163 is smaller than a distance between the second semiconductor laser light source 22 and the principal point H2 of the second condensing optical system 42.

The condensing optical system 164 is provided between the semiconductor laser light source 144 and the mirror 156. A distance between the semiconductor laser light source 144 and the principal point of the condensing optical system 164 is smaller than a distance between the semiconductor laser light source 143 and the principal point of the condensing optical system 163.

The condensing optical systems 161, 162, 163, and 164 are, for example, condenser lenses. In the example shown in the drawing, the condensing optical systems 161, 162, 163, and 164 are convex lenses. The effective diameters of light in the condensing optical systems 41 and 42, 161, 162, 163, and 164 may be the same.

In the laser module 500, light beams emitted from the semiconductor laser light sources 21, 22, 141, 142, 143, and 144 can be condensed at the condensing point F by the condensing optical systems 41, 42, 161, 162, 163, and 164, respectively. For this reason, it is possible to achieve a high output.

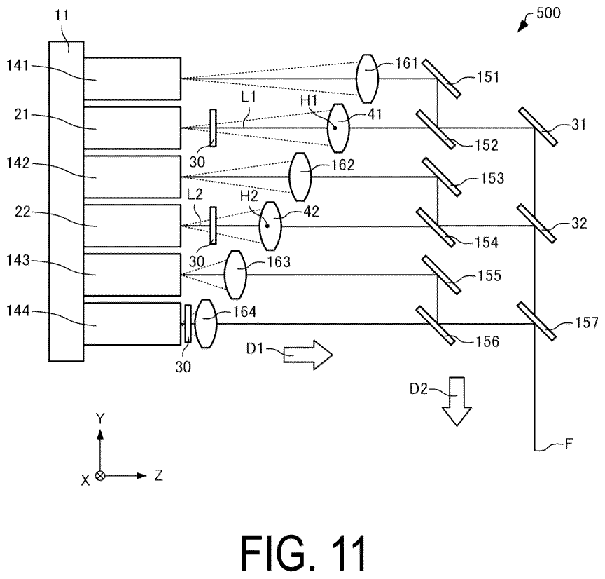

The semiconductor laser light sources 21, 22, 141, 142, 143, and 144 may emit the same polarized light. In this case, as shown in FIG. 11, the λ/2 plate 30 is provided in an optical path from the first semiconductor laser light source 21 to the first condensing optical system 41, an optical path from the second semiconductor laser light source 22 to the second condensing optical system 42, and an optical path from the semiconductor laser light source 144 to the condensing optical system 164. This allows the light emitted from the semiconductor laser light sources 21 and 22, and 144 to be converted, for example, from S-polarized to P-polarized light.

Furthermore, the number of semiconductor laser light sources and the number of mirrors are not particularly limited.

### 3. LASER PROCESSING MACHINE

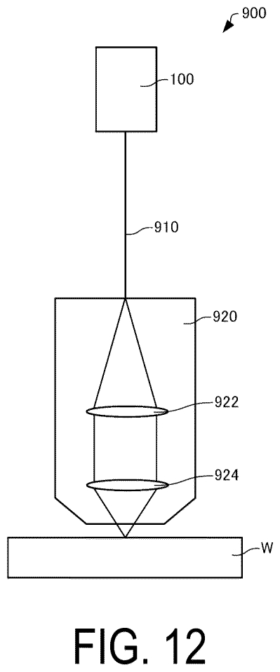

Next, a laser processing machine according to the present embodiment will be described with reference to the drawings. FIG. 12 is a diagram schematically showing a laser processing machine 900 according to the present embodiment.

As shown in FIG. 12, the laser processing machine 900 includes, for example, a laser module 100, an optical fiber 910, and a machining head 920.

Light emitted from the laser module 100 passes through the optical fiber 910 and is guided to the machining head 920.

The laser processing machine 900 processes a workpiece W. Specifically, in the laser processing machine 900, the machining head 920 is moved relative to the workpiece W, and light is emitted from the machining head 920 to process the workpiece W. The machining head 920 includes lenses 922 and 924. The lenses 922 and 924 condense light emitted from the optical fiber 910 and guide it to the workpiece W. The material of the workpiece W is not particularly limited, and may be a metal, a resin, or ceramic. Although not shown in the drawing, the laser processing machine 900 may not include the optical fiber 910, and the laser module 100 may be incorporated into the machining head 920.

There are no particular limitations on the use of the laser processing machine according to the present disclosure. The laser processing machine according to the present disclosure may be a processing machine for cutting the workpiece W or drilling holes in the workpiece W. In addition, the laser processing machine according to the present disclosure may also be, for example, a laser cleaner that removes rust and the like from a metal with a laser beam, may be a laser annealing device that heats the surface of a metal or a resin with a laser beam, or may be a 3D printer.

In addition, the laser processing machine according to the present disclosure may include a laser module other than the laser module 100 as long as it is a laser module according to the present disclosure.

### 4. EXPERIMENTAL EXAMPLE

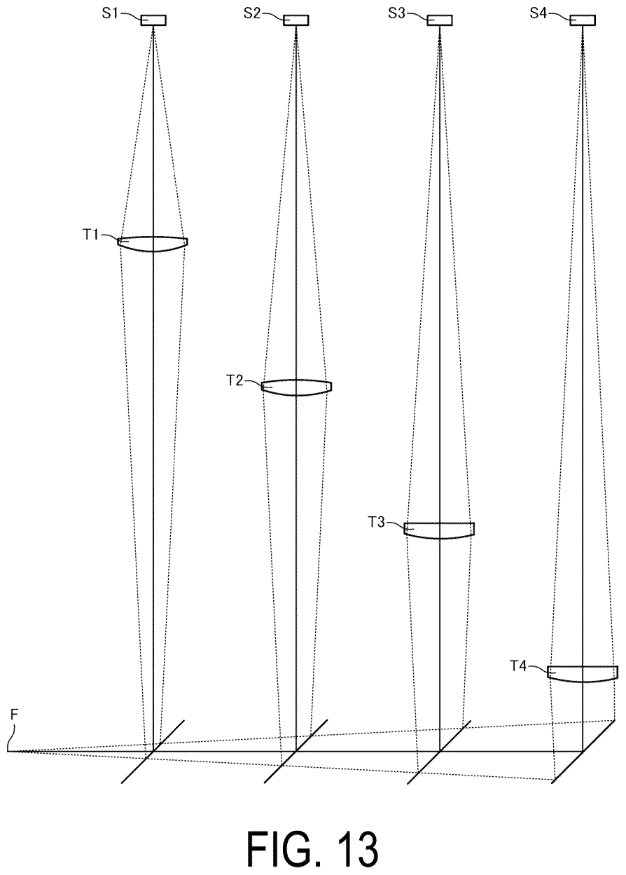

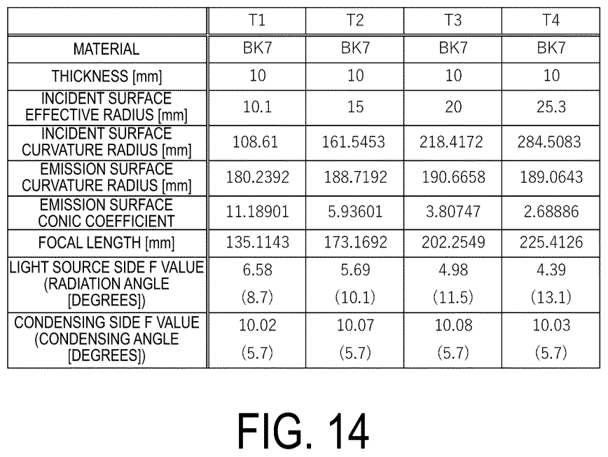

Next, a simulation was performed as an experimental example. FIG. 13 is a diagram showing a simulation. FIG. 14 is a table showing the simulation.

In the simulation, four light sources S1, S2, S3, and S4 were used, as shown in FIG. 13. The wavelengths of light beams emitted from the light sources S1, S2, S3, and S4 were 1100 nm, 1000 nm, 900 nm, and 800 nm, respectively. The light beams emitted from light sources S1, S2, S3, and S4 were incident on lenses T1, T2, T3, and T4, respectively. The conditions of the lenses T1, T2, T3, and T4 are as shown in FIG. 14. “BK7” in FIG. 14 is borosilicate crown glass with a refractive index of 1.51680 in a d line represented by “N-BK7” made by SCHOTT. Other compatible glass materials, such as “S-BSL7” made by OHARA, may also be adopted.

As shown in FIGS. 13 and 14, an angle of emitted light becomes wider as a distance from the light source to a condensing point increases, and light is condensed such that a condensing angle at the condensing point is uniform at 5.7 degrees. In addition, as shown in FIGS. 13 and 14, a focal length increases as a distance from the light source to the condensing point becomes longer. From the above, it is demonstrated by a simulation that the characteristics shown in the present disclosure are established in principle.

The embodiment and the modification examples described above are merely examples, and are not intended as limiting. For example, the embodiment and the modification examples can also be combined together as appropriate.

The present disclosure includes configurations that are substantially identical to the configurations described in the embodiment, for example, configurations with identical functions, methods and results, or with identical advantages and effects. In addition, the present disclosure includes configurations obtained by replacing non-essential portions of the configurations described in the embodiment. The present disclosure also includes configurations that achieve the same effects as the configurations described in the embodiments or configurations that can achieve the same advantages. Further, the present disclosure includes configurations obtained by adding known techniques to the configurations described in the embodiment.

The following contents are derived from the embodiment and the modification examples described above.

According to an aspect of the present disclosure, a laser module includes
a first substrate,
a first semiconductor laser light source that is provided on a first plane of the first substrate and emits first light in a first direction that is a direction perpendicular to the first plane,
a second semiconductor laser light source that is provided on the first plane and emits second light in the first direction,
a first mirror that reflects the first light emitted from the first semiconductor laser light source in the first direction,
a second mirror that transmits the first light reflected by the first mirror in a second direction different from the first direction and reflects the second light emitted from the second semiconductor laser light source in the second direction, and
a first condensing optical system that is provided between the first semiconductor laser light source and the first mirror, and a second condensing optical system that is provided between the second semiconductor laser light source and the second mirror,
wherein a radiation angle of the first light emitted from the first semiconductor laser light source is smaller than a radiation angle of the second light emitted from the second semiconductor laser light source,
a distance between the first semiconductor laser light source and a principal point of the first condensing optical system is greater than a distance between the second semiconductor laser light source and a principal point of the second condensing optical system, and
an optical path length from the first semiconductor laser light source to the second mirror is greater than an optical path length from the second semiconductor laser light source to the second mirror.

According to the laser module, the positions of the first semiconductor laser light source and the second semiconductor laser light source can be easily adjusted.

In an aspect of the laser module,
the first light and the second light may be incident on the second mirror as light beams having different polarization directions, and
the second mirror may be a polarization beam combiner.

According to the laser module, the first light and the second light can be multiplexed in the second mirror.
In an aspect of the laser module,
the first light and the second light may have different wavelengths, and
the second mirror may be a dichroic mirror.

According to the laser module, the first light and the second light can be multiplexed in the second mirror.

The laser module according to an aspect of the present disclosure may further include
a second substrate that is provided to face the first substrate,
a third semiconductor laser light source that is provided on a second plane of the second substrate and emits third light in a third direction opposite to the first direction,
a fourth semiconductor laser light source that is provided on the second plane and emits fourth light in the third direction,
a third mirror that reflects the third light emitted from the third semiconductor laser light source in the third direction,
a fourth mirror that transmits the third light reflected by the third mirror in the second direction and reflects the fourth light emitted from the fourth semiconductor laser light source in the second direction, and
a fifth mirror that reflects the first light and the second light from the second mirror in the second direction and transmits the third light and the fourth light from the fourth mirror in the second direction.

According to the laser module, it is possible to achieve a high output.

In an aspect of the laser module,
the first light and the second light may be incident on the fifth mirror as first polarized light,
the third light and the fourth light may be incident on the fifth mirror as second polarized light different from the first polarized light, and
the fifth mirror may be a polarization beam combiner.

According to the laser module, the first light, the second light, the third light, and the fourth light can be multiplexed.

In an aspect of the laser module,
the first light and the second light may be light with a first wavelength,
the third light and the fourth light may be light with a second wavelength different from the first wavelength, and
the fifth mirror may be a dichroic mirror.

According to the laser module, the first light, the second light, the third light, and the fourth light can be multiplexed.

In an aspect of the laser module,
the first semiconductor laser light source and the second semiconductor laser light source may be photonic crystal surface emitting lasers.

According to the laser module, the radiation angle of the first light and the radiation angle of the second light can be adjusted by composite modulation.

According to an aspect of the present disclosure, a laser processing machine includes the laser module.

What is claimed is:

1. A laser module comprising:
a first substrate;
a first semiconductor laser light source that is provided on a first plane of the first substrate and emits first light in a first direction that is a direction perpendicular to the first plane;
a second semiconductor laser light source that is provided on the first plane and emits second light in the first direction;
a first mirror that reflects the first light emitted from the first semiconductor laser light source in the first direction;
a second mirror that transmits the first light reflected by the first mirror in a second direction different from the first direction and reflects the second light emitted from the second semiconductor laser light source in the second direction; and
a first condensing optical system that is provided between the first semiconductor laser light source and the first mirror, and a second condensing optical system that is provided between the second semiconductor laser light source and the second mirror,
wherein a radiation angle of the first light emitted from the first semiconductor laser light source is smaller than a radiation angle of the second light emitted from the second semiconductor laser light source,
a distance between the first semiconductor laser light source and a principal point of the first condensing optical system is greater than a distance between the second semiconductor laser light source and a principal point of the second condensing optical system, and
an optical path length from the first semiconductor laser light source to the second mirror is greater than an optical path length from the second semiconductor laser light source to the second mirror.

2. The laser module according to claim 1, wherein
the first light and the second light are incident on the second mirror as light beams having different polarization directions, and
the second mirror is a polarization beam combiner.

3. The laser module according to claim 1, wherein
the first light and the second light have different wavelengths, and
the second mirror is a dichroic mirror.

4. The laser module according to claim 1, further comprising:
a second substrate that is provided to face the first substrate;
a third semiconductor laser light source that is provided on a second plane of the second substrate and emits third light in a third direction opposite to the first direction;
a fourth semiconductor laser light source that is provided on the second plane and emits fourth light in the third direction;
a third mirror that reflects the third light emitted from the third semiconductor laser light source in the third direction;
a fourth mirror that transmits the third light reflected by the third mirror in the second direction and reflects the fourth light emitted from the fourth semiconductor laser light source in the second direction; and
a fifth mirror that reflects the first light and the second light from the second mirror in the second direction and transmits the third light and the fourth light from the fourth mirror in the second direction.

5. The laser module according to claim 4, wherein
the first light and the second light are incident on the fifth mirror as first polarized light,
the third light and the fourth light are incident on the fifth mirror as second polarized light different from the first polarized light, and
the fifth mirror is a polarization beam combiner.

6. The laser module according to claim 4, wherein
the first light and the second light are light with a first wavelength,
the third light and the fourth light are light with a second wavelength different from the first wavelength, and
the fifth mirror is a dichroic mirror.

7. The laser module according to claim 1, wherein the first semiconductor laser light source and the second semiconductor laser light source are photonic crystal surface emitting lasers.

8. A laser processing machine comprising the laser module according to claim 1.
